(19) United States
(12) Patent Application Publication
(10) Pub. No.: US 2026/0150673 A1
(43) Pub. Date: May 28, 2026

(54) INTEGRATED POWER STAGE ASSEMBLY WITH ACTIVE/INACTIVE REGIONS

(71) Applicant: Infineon Technologies Austria AG, Villach (AT)

(72) Inventors: Angela Kessler, Sinzing (DE); Andreas GRASSMANN, Sinzing (DE)

(21) Appl. No.: 18/956,623

(22) Filed: Nov. 22, 2024

(51) Int. Cl. H01L 23/373; H01L 23/538; H01L 25/065

(52) U.S. Cl. CPC H10W 40/253; H10W 70/60; H10W 70/611; H10W 90/00; H10W 90/28; H10W 90/288

(57) ABSTRACT

An assembly as discussed herein includes: a first semiconductor chip substrate including an active region and an inactive region, the active region of the first semiconductor chip substrate fabricated to include first circuitry, the first circuitry being active circuitry, the inactive region of the first semiconductor chip substrate being void of active circuitry; and second circuitry coupled to the first semiconductor chip substrate, the second circuitry affixed to the inactive region of the first semiconductor chip substrate, the inactive region operative to receive and convey heat generated by the second circuitry.

### BACKGROUND

A conventional power stage assembly can be configured to include multiple switches such as a high side switch and a low side switch that are operated to control delivery of current to a circuit component such as an inductor or multiple circuit components. In addition to the multiple switches, the conventional power stage can be configured to include driver circuitry to control the multiple switches.

One type of conventional power stage assembly includes a so-called side by side solution, where respective multiple switches in the power stage are disposed in a single circuit layer. In general, the side-by-side solution of the power stage assembly provides good thermal performance. However, intrinsic to the side-by-side solution is high stray inductance, which negatively impacts performance associated with the conventional power stage assembly.

Another type of conventional power stage assembly includes a so-called stack solution of circuit components, where circuit components are stacked upon each other to fabricate a respective power converter assembly. Such a conventional stack solution provides a smaller sized circuit footprint and reduced parasitic effects. However, top chips in the conventional power stage assembly heat respective top chips in the stack, potentially causing damage to same.

### BRIEF DESCRIPTION

Implementation of clean energy (or green technology) is very important to reduce our impact as humans on the environment. In general, clean energy includes any evolving methods and materials to reduce an overall toxicity to the environment as caused by energy consumption.

This disclosure includes the observation that it is desirable to fabricate switch circuit assemblies to achieve better power efficiency and compactness. To this end, the one or more examples as discussed herein may provide one or more benefits such as:
Minimum footprint for close proximity to a load such as a processor or other circuit components
Lowest parasitics for high efficiency
Good thermal performance for high power density

As a more specific example, an assembly such as associated with a power converter as discussed herein can be configured to include: a first semiconductor chip substrate including an active region and an inactive region. The active region of the first semiconductor chip substrate may be fabricated to include first circuitry, where the first circuitry is so-called active circuitry potentially supporting flow of current. The inactive region of the first semiconductor chip substrate may be void of active circuitry. Second circuitry of the assembly may be coupled to the first semiconductor chip substrate. The second circuitry may be affixed to the interactive region of the first semiconductor chip substrate, the inactive region may be operative to receive and convey heat generated by the second circuitry.

Note that the inactive region such as including the void of active circuitry as discussed herein may be a region in which no current flows because there is no active circuitry in the inactive region. In one example, the lack of flow of current through the inactive region of the first semiconductor chip substrate results in the non-generation of heat by the inactive region. In such an instance, the inactive region supports good flow of heat (i.e., thermal energy) from the second circuitry to an entity such as a host substrate to which the first semiconductor chip substrate is attached.

In one example, the second circuitry may include driver circuitry coupled to the first semiconductor chip substrate, the driver circuitry may be operative to control operation of the first circuitry. The first circuitry may include a first switch controlled by the driver circuitry; the second circuitry may include a second switch controlled by the driver circuitry.

In another example, the first circuitry may be a first vertical field effect transistor. The second circuitry may be a second vertical field effect transistor. Further, a first layer of metal may be disposed on a first surface of the first semiconductor chip substrate; and a second layer of metal may be disposed on a second surface of the first semiconductor chip substrate, the second surface disposed opposite the first surface. The first circuitry may be a first switch. The source node of the first switch may be directly coupled to the first layer of metal; a drain node of the second switch circuitry may be directly coupled to the first layer of metal.

Still further, note that the second region of the first semiconductor chip substrate can be configured to provide a thermally conductive path between a first surface of the first semiconductor chip substrate through the second region to a second surface of the first semiconductor chip substrate.

In yet further examples, the first semiconductor chip substrate may be a first monolithic semiconductor substrate including the active region and the inactive region; the second circuitry may include a second semiconductor chip substrate, the second semiconductor chip substrate being a second monolithic semiconductor substrate.

In accordance with another example, the first circuitry may be a first switch; the second circuitry may be a second switch. The assembly may further include an electrically conductive path coupling the first switch and the second switch, the electrically conductive path may directly couple a source node of the first switch to a drain node of the second switch.

Further examples as discussed herein include an implementation which the inactive region includes a first portion and a second portion separated by a portion of the active region. The first circuitry may be a first switch. The second circuitry may include a second switch and driver circuitry, the driver circuitry may be operative to control operation of the first switch and the second switch, the driver circuitry may be coupled to a surface of the first semiconductor chip substrate over the first portion of the inactive region, the second switch may be coupled to the surface of the first semiconductor chip substrate over the second portion of the inactive region.

The active region of the first semiconductor chip substrate may be operative to generate heat; and the inactive region of the first semiconductor chip substrate is not operative to generate heat.

Another example as discussed herein includes an apparatus comprising the host substrate and an assembly as previously discussed. The assembly is coupled to the host substrate where the first circuitry may be affixed to a surface of the host substrate, the first semiconductor chip substrate may be disposed between the second circuitry and the host substrate.

In another example, the first circuitry is a high side switch of a power converter. The second circuitry is a low side switch of the power converter. The apparatus may further include: i) a first electrically conductive path extending from the surface of the host and substrate to a first node of the high side switch, wherein the high side switch is disposed between the first node of the high side switch and the surface of the host substrate, and ii) a second electrically conductive path extending from the surface of the host substrate to a first node of the low side switch, wherein a combination of the low side switch and the first semiconductor chip substrate are disposed between the first node of the low side switch and the surface of the host substrate.

In still another example, the first circuitry may be a low side switch of a power converter; the second circuitry may be a high side switch of the power converter. The apparatus may further include: i) a first electrically conductive path extending from the surface of the host substrate to a first node of the low side switch, wherein the low side switch is disposed between the first node of the low side switch and the surface of the host substrate, and ii) a second electrically conductive path extending from the surface of the host substrate to a first node of the high side switch, wherein a combination of the high side switch and the first semiconductor chip substrate are disposed between the first node of the high side switch and the surface of the host substrate.

In still further examples, the assembly as discussed herein may include an electrically conductive path extending between a first node of the first switch and a first node of the second switch; and the first node of the first switch may be disposed between the first semiconductor chip substrate and the electrically conductive path. The second circuitry may be disposed between the electrically conductive path and the first semiconductor chip substrate.

In one example, the first semiconductor chip substrate is disposed in a first material layer of a component stack, the assembly further comprises: a first electrically conductive path disposed in the first material layer adjacent to the first semiconductor chip substrate, the electrically conductive path coupled to a first node of the second circuitry; and a second electrically conductive path directly connecting the first circuitry and the second circuitry in series. The first circuitry may include a first switch; the second circuitry may include a second switch. The inactive region of the first semiconductor chip substrate may be disposed in the first material layer between the first switch and the first electrically conductive path; and the second circuitry may include driver circuitry disposed adjacent to the second switch and above the inactive region of the first semiconductor chip substrate.

Yet further, the first circuitry in the active region of the first semiconductor chip substrate may be disposed between the inactive region and the first electrically conductive path; and the second circuitry may include driver circuitry disposed adjacent to the second switch circuitry above the inactive region.

According to another example, the assembly as discussed herein can be configured to include a first electrically conductive path connecting the first circuitry and the second circuitry in series, the first electrically conductive path extending to a surface of a host substrate to which the assembly is attached.

According to still further examples as discussed herein, the assembly may include a second electrically conductive path; where a first portion of the second electrically conductive path is a circuit node providing connectivity between the second circuitry and the inactive region of the first semiconductor chip substrate; and where a second portion of the second electrically conductive path extends between the circuit node and the surface of the host substrate.

Further examples as discussed herein include a method comprising: receiving a first semiconductor chip substrate including an active region and an inactive region, the active region of the first semiconductor chip substrate fabricated to include first circuitry, the first circuitry being active circuitry, the inactive region of the first semiconductor chip substrate being void of active circuitry; and coupling second circuitry to the first semiconductor chip substrate, the second circuitry affixed to the second region of the first semiconductor chip substrate.

As discussed herein, techniques herein are well suited for use in the field of implementing one or more switch circuit assemblies to control delivery of current through multiple switches. However, it should be noted that examples herein are not limited to use in such applications and that the techniques discussed herein are well suited for other applications as well.

Additionally, note that although each of the different features, techniques, configurations, etc., herein may be discussed in different places of this disclosure, it is intended, where suitable, that each of the concepts can optionally be executed independently of each other or in combination with each other. Accordingly, the one or more present inventions as described herein can be implemented and viewed in many different ways.

Also, note that this preliminary discussion of examples herein (BRIEF DESCRIPTION OF EXAMPLES) purposefully does not specify every example and/or incrementally novel aspect of the present disclosure or claimed invention(s). Instead, this brief description only presents general examples and corresponding points of novelty over conventional techniques. For additional details and/or possible perspectives (permutations) of the invention(s), the reader is directed to the Detailed Description section (which is a summary of examples) and corresponding figures of the present disclosure as further discussed below.

### BRIEF DESCRIPTION OF THE DRAWINGS

FIG. 1 is an example diagram illustrating a switch circuit implemented in the switch circuit assembly as discussed herein.

FIG. 2 is an example diagram illustrating a switch circuit assembly as discussed herein.

FIG. 3 is an example diagram illustrating a switch circuit assembly as discussed herein.

FIG. 4 is an example diagram illustrating a switch circuit assembly including a flipped driver circuit as discussed herein.

FIG. 5 is an example diagram illustrating a switch circuit assembly including a flipped driver circuit as discussed herein.

FIG. 6 is an example diagram illustrating implementation of one or more metal clips in a switch circuit assembly as discussed herein.

FIG. 7 is an example diagram illustrating implementation of one or more metal clips in a switch circuit assembly as discussed herein.

FIG. 8 is an example diagram illustrating implementation of an electrically conductive path connecting multiple switches in a switch circuit assembly as discussed herein.

FIG. 9 is an example diagram illustrating implementation of an electrically conductive path connecting multiple switches in a switch circuit assembly as discussed herein.

FIG. 10 is an example diagram illustrating implementation of a metal layer providing electrical connectivity of a switch in a switch circuit assembly to a host substrate as discussed herein.

FIG. 11 is an example diagram illustrating implementation of a metal layer providing electrical connectivity of a switch in a switch circuit assembly to a host substrate as discussed herein.

FIG. 12 is an example diagram illustrating implementation of a metal layer providing electrical connectivity of a switch in a switch circuit assembly to a host substrate as discussed herein.

FIG. 13 is an example diagram illustrating implementation of a metal layer providing electrical connectivity of a switch in a switch circuit assembly to a host substrate as discussed herein.

FIG. 14 is an example diagram illustrating implementation of a metal layer providing electrical connectivity of a switch in a switch circuit assembly to a host substrate as discussed herein.

FIG. 15 is an example diagram illustrating implementation of a metal layer providing electrical connectivity of multiple switches in a switch circuit assembly to a host substrate as discussed herein.

FIG. 16 is an example diagram illustrating implementation of a first electrically conductive path providing electrical connectivity of multiple switches in a switch circuit assembly to a host substrate and implementation of a second electrically conductive path to provide an input voltage to a switch in the switch circuit assembly as discussed herein.

FIG. 17 is an example method illustrating fabrication of a switch circuit assembly as discussed herein.

The foregoing and other objects, features, and advantages of the invention will be apparent from the following more particular description of preferred examples herein, as illustrated in the accompanying drawings in which like reference characters refer to the same parts throughout the different views. The drawings are not necessarily to scale, with emphasis instead being placed upon illustrating the examples, principles, concepts, etc.

### DETAILED DESCRIPTION

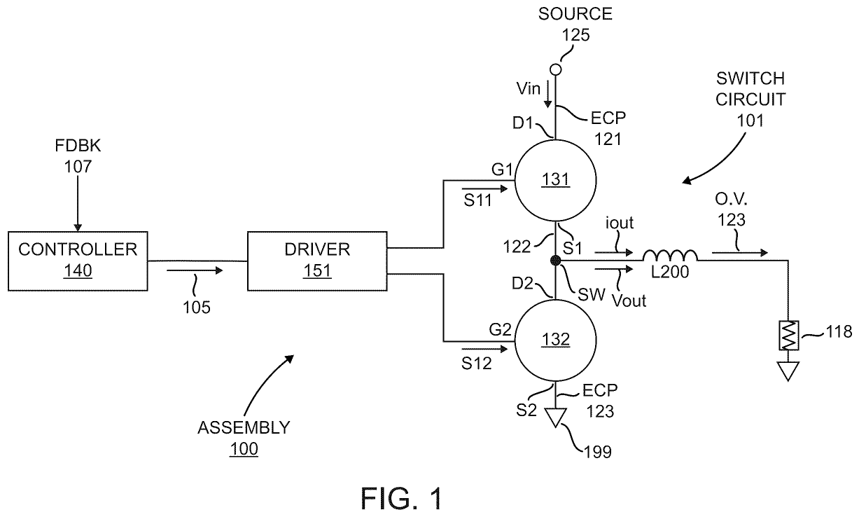

Now, more specifically, FIG. 1 is an example diagram illustrating a switch circuit for implementation in a switch circuit assembly as discussed herein.

In this example, the switch circuit 101 as shown in FIG. 1 (such as implemented via different instances of the assembly 100 in the following drawings and discussion) includes controller 140, driver circuitry 151, first switch circuitry 131, second switch circuitry 132, and inductor L200.

In one example, a combination of the switch circuitry 131 and the switch circuitry 132 are disposed in series between the power source 125 (input voltage source) supplying input voltage (Vin) to the drain node D1 of the switch circuitry 131. The switch circuit 101 can be referenced with respect to the ground reference voltage 199. The switch node SW (such as electrically conductive path 122 fabricated from metal or other suitable material) provides connectivity between the switch circuitry 131 and the switch circuitry 132. The switch node SW also provides connectivity of the switch circuitry 131 and the switch circuitry 132 to the inductor L200.

Note further that the switch circuitry and corresponding switch circuit 101 as discussed herein can be implemented in any suitable manner. In one example, the switch circuitry 131 is a first field effect transistor (or multiple transistors in parallel) including a gate node G1, a drain node D1, and a source node S1. In a similar manner, the switch circuitry 132 may be a second field effect transistor (or multiple transistors in parallel) including a gate node G2, drain node D2, and source node S2.

As further shown, the electrically conductive path 121 (such as metal or other suitable material) provides electrical connectivity between the input voltage source 125 and the drain node D1 of the switch circuitry 131. As previously discussed, the source node S1 of the switch circuitry 131 may be directly connected to the drain node D2 of the switch circuitry 132 via the switch node SW (such as one or more electrically conductive paths including electrically conductive path 122). Further, the source node S2 of the switch circuitry 132 may be connected directly to the ground reference 199 such as via the electrically conductive path 123.

During operation, the controller 140 produces the control signals 105 supplied to the driver circuitry 151. The state of the control signals 105 as produced by the controller 140 may depend upon the feedback 107 such as input indicating an output voltage 123 supplied to the dynamic load 118. The control signals 105 indicate how to control the respective switch circuitry 131 and switch circuitry 132. The driver circuitry 151 converts the control signals 105 into the control signals S11 and S12).

In general, in one example, the driver circuitry 151 switches between activating the switch circuitry 131 and switch circuitry 132 such that the current through the respective inductor L200 is supplied by either the current through the switch circuitry 131 or current through the switch circuitry 132.

More specifically, during a first portion of a switching control cycle, the driver circuitry 151 produces the control signal S11 (applied to the gate node G1) to a logic high to activate the respective switch circuitry 131, providing a low impedance path between the drain node D1 and the source node S1. Additionally, during the first portion of the switching cycle, the driver circuitry 151 produces the control signal S12 (applied to the gate node G2) to a logic low to deactivate the respective switch circuitry 132, providing a high impedance path between the drain node D2 and the source node S2. Thus, during the first portion of a switching control cycle, the control signal S11 is a logic high and control signal S12 is a logic low.

During a second portion of the switching control cycle, the driver circuitry 151 produces the control signal S11 to a logic low to deactivate the respective switch circuitry 131, providing a high impedance path between the drain node D1 and the source node S1. Additionally, during the second portion of the switching cycle, the driver circuitry 151 produces the control signal S12 to a logic high to activate the respective switch circuitry 132, providing a low impedance path between the drain node D2 and the source node S2. Thus, during the second portion of a switching control cycle, the control signal S11 is a logic low and control signal S12 is a logic high.

During one or more third portions (such as during so-called dead times) of the switching cycle, the driver circuitry 151 produces the control signals S11 and S12 to simultaneously deactivate both the switch circuitry 131 and the switch circuitry 132 to an OFF-state.

Further, by way of nonlimiting example, it is noted again that the switch circuit 101 can be configured to provide feedback 107 indicating a respective magnitude of an output voltage 123 outputted from the inductor L200 to the load 118. As previously discussed, the controller 140 can be configured to use the feedback 107 as a basis in which to determine how to control switching of the respective switch circuitry 131 and switch circuitry 132 via the one or more control signals 105.

As further discussed herein, the switch circuit 101 as shown in FIG. 1 is shown by way of nonlimiting example only. The assembly 100 as discussed herein can be configured in any suitable manner to include switch circuitry 131 and switch circuitry 132 to control conveyance of current supplied by the switch node SW to any circuit.

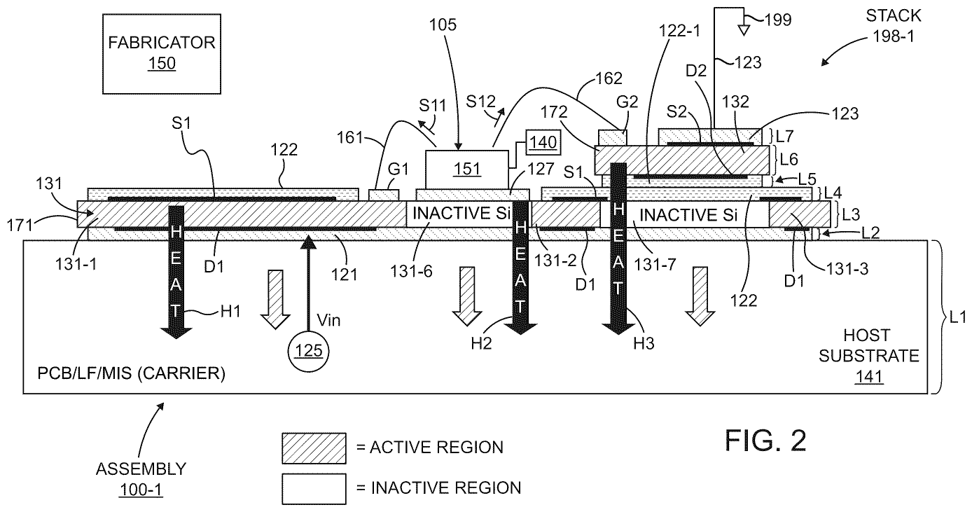

FIG. 2 is an example diagram illustrating a switch circuit assembly as discussed herein.

In this general example, the assembly 100-1 fabricated by the fabricator 150 includes stack 198-1 of layers and/or circuit components supporting conveyance of current supplied by a switch node SW to a target component such as an inductor (L200) or other suitable entity. An example of a switch circuit 101 (FIG. 1) supported by the assembly 100-1 (such as an first instance of the assembly 100) is shown in FIG. 2.

Specifically, in FIG. 2, the fabricator 150 in this example produces the assembly 100-1 (such as a first instance of the assembly 100 in FIG. 1) to include a host substrate 141 disposed at the layer L1 such as printed circuit board or other suitable entity, electrically conductive path 121 (such as metal or other suitable material) disposed in the layer L2, substrate such as a first semiconductor chip substrate 171 disposed in the layer L3, electrically conductive path 127 and electrically conductive path 122 (such as metal or other suitable material) disposed in the layer L4, electrically conductive material 122-1 disposed in layer L5, substrate such as a second semiconductor chip substrate 172 disposed in layer L6, and electrically conductive material such as gate node G2 and source node layers such as associated with source node S2 in layer 7.

The stack 198-1 can include any number of layers of circuit components or material.

It is noted that the drain node D1 associated with the active regions (131-1, 131-2, 131-3, etc.) of the first semiconductor chip substrate 171 are connected to the electrically conductive path 121 affixed to the host substrate 141. The semiconductor chip substrate 171 and corresponding active regions are therefore affixed to the electrically conductive path 121 in layer L2.

As further shown, and as previously discussed, the driver circuitry 151 receives control signals 105 from the controller 140. The controller 140 can be affixed to any suitable part of the assembly 100-1 or the controller 140 can be disposed at a location other than the assembly 100-1. Based on the received control signals 105, the controller 140 produces the control signals S11 and S12 to control the respective switch 131 in layer L3 and switch 132 in layer L6.

More specifically, the driver circuitry 151 produces the control signal S11 and transmits it over the electrically conductive path 161 (such as a wire bond or other suitable entity) to the gate node G1 of the first switch circuitry 131 disposed in the first semiconductor chip substrate at layer L3. The host substrate 141 or other suitable entity such as a power supply 125 supplies the input voltage Vin and corresponding current to the electrically conductive path 121, which further supplies the input voltage Vin and corresponding current to the drain node D1 (a.k.a., drain node regions D1) of the switch circuitry 131 coupled to the active regions (131-1, 131-2, 131-3, etc.) of the substrate 171 in the layer L3 of the stack 198-1.

Depending upon the state of the control signal S11 applied to the gate G1, the first switch circuitry 131 implemented in the active regions of substrate 171 in the layer L3 selectively controls conveyance of the input voltage and a corresponding current from the input voltage source 125 through the first switch circuitry 131 to the source node S1 and corresponding electrically conductive path 122. For example, driving the gate node G1 is with a logic high control signal S11, results in a low impedance path between the drain node D1 and the source node S1.

Additionally, the driver circuitry 151 produces the control signal S12 and transmits it over the electrically conductive path 162 (such as a wire bond or other circuit path) to the gate node G2 of the first switch circuitry 132 disposed in the second substrate 172 such as a second semiconductor chip substrate at layer L6. The source node S2 of the switch 132 is connected to the ground reference voltage 199. When the signal S1 to supplied to the gate node G2 is a logic high, the switch circuitry 132 operates in an ON-state providing a low impedance path between the drain node D2 and the source node S2. In such an instance, the source node S2 supplies the ground reference voltage 199 to the drain node D2 of the switch circuitry 132 disposed in the active region of the layer L6. Accordingly, depending upon the state of the control signal S12 applied to the gate G2, the second switch circuitry 132 implemented in the active regions of layer L6 controls conveyance of the ground reference voltage 199 and a corresponding current through the second switch circuitry 132 from the source node S2 to the drain node D2.

The implementation of so-called active regions (such as regions 131-1, 131-2, 131-3, etc.) in the substrate 171 such as a first semiconductor chip substrate in layer L3 represent the corresponding switch circuitry 131. The implementation of so-called active regions in the substrate 172 such as a second semiconductor chip substrate in layer L6 represent the corresponding switch circuitry 132.

As further shown, the substrate 171 in layer L3 advantageously includes inactive regions such as regions that are void of regions active circuitry. In one example, the inactive regions do not support flow of current. Thus, such regions do not generate heat.

During activation of the respective switch circuitry 131 to an on state, the active regions 131-1, 131-2, 131-3, etc., in the substrate 171 support flow of a respective current from the input voltage Vin and corresponding current received at the drain node D1 through the active regions to the corresponding source node S1. The heat generated based on flow of current through the switch circuit 131 is conveyed from the active regions of the substrate 171 to the host substrate 141. In other words, during activation of the switch circuitry 131, because the corresponding drain D1 to source S1 path has some amount of ON resistance even in the ON-state of the switch circuitry 131, the activated switch circuitry 131 and corresponding active regions produce heat H1 that is conveyed to the substrate 141.

It is further noted that operation of the driver circuitry 151 results in generation of heat H2 that is conveyed through the inactive region 131-6 of the substrate 171. The void of activate circuitry in the inactive region 131-6 reduces the amount of heat that would otherwise need to be transferred to the host substrate 141 if the inactive region 131-6 was active circuitry providing a low impedance path. In other words, because the inactive region 131-6 does not include active circuitry supporting current flow, the inactive region 131-6 itself does not produce heat during activation of the switch circuit 131, enabling the inactive region 131-6 supporting conveyance of heat H2 generated by the driver circuitry 151 through the inactive region 131-6 to the host substrate 141.

It is further noted that operation of the driver circuitry 151 to an on state results in generation of heat H3 originating from the switch 132 when it is activated (ON-state) to convey respective current from the ground reference voltage 199 through the active region of the substrate 172 (instantiation of the switch circuitry 132) to the electrically conductive path 122 (122-1) such as representing the switch node SW. As previously discussed, the void of activate circuitry in the inactive region 131-7 reduces the amount of heat that would otherwise need to be transferred to the host substrate 141 if the inactive region 131-7 was implemented as an active region. In other words, the inactive region 131-7 itself does not produce heat during activation of the switch circuit 131, enabling the inactive region 131-7 to support conveyance of heat H3 generated by the switch circuitry 132 through the inactive region 131-7 to the host substrate 141 for dissipation.

Thus, in summary, the assembly 100-1 as discussed herein includes a first semiconductor chip substrate 171 including an active region or multiple active regions and an inactive region or multiple inactive regions. The fabricator 150 fabricates the switch circuitry 131 in the substrate 171 to include any number of active regions (131-1, 131-2, 131-3, etc.) supporting control of current from the input voltage source 125 to the switch node SW (such as electrically conductive path 122 or electrically conductive path 124). During operation, the control of current through the active regions of the first switch circuitry 131 in the first semiconductor chip substrate 171 results in generation of heat H1 that is conveyed from the first semiconductor chip substrate 171 through the electrically conductive path 121 to the host substrate 141, where the host substrate 141 dissipates the received heat H1 generated based on operation of the switch circuitry 131.

As previously discussed, the substrate 171 includes one or more inactive regions (such as inactive region 131-6, 131-7, etc.), which are void of active circuitry that generates heat. The second circuitry such as switch circuitry 132 is coupled to the first semiconductor chip substrate 171. More specifically, the switch circuitry 132 is affixed directly above the inactive region 131-7, where the inactive region 131-7 of the substrate 171 does not itself generate heat but is a good conductor of heat H3 that is conveyed through the inactive region 131-7 to the host substrate 141. Thus, because the inactive region 131-7 itself does not generate heat, the inactive region 131-7 is able to convey the heat H3 without overheating of the inactive region 131-7 or any circuit components in the stack 198-1.

As previously discussed, in one example, note that the secondary circuitry in the stack 198-1 may include the driver circuitry 151 as well as the corresponding switch circuitry 132.

It is further noted that the switch circuitry 131 disposed in the substrate 171 in layer L3 may be implemented as a first vertical field effect transistor disposed in the stack 198-1. Further, the switch circuitry 132 disposed in the layer L6 can be implemented as a second vertical field effect transistor disposed in the stack 198-1.

The electrically conductive path 121 (layer of metal in layer L2) may be a first layer of metal disposed on a first surface of the first semiconductor chip substrate 171; and the electrically conductive path 122 (layer of metal and layer L4) may be a second layer of metal disposed on a second surface of the first semiconductor chip substrate 171, where the second surface is disposed opposite the first surface. As previously discussed, a drain node D2 of the second switch circuitry 132 may be directly coupled (such as via electrically conductive path 122, 122-1) to the source node S1 of the first switch circuitry 131.

Further, the inactive region of the first semiconductor chip substrate 171 such as the inactive region 131-7 provides a thermally conductive path between a first surface of the first semiconductor chip substrate 171 at the interface between layer L3 and layer L4 through the inactive region 131-7 to a second surface of the first semiconductor chip substrate 171 coupled to the electrically conductive path 121 and corresponding host substrate 141.

In further examples, the first semiconductor chip substrate 171 is a first monolithic semiconductor substrate including the active region (such as one or more of active region 131-1, active region 131-2, active region 131-3, etc.) and the inactive region (such as inactive region 131-6, inactive region 131-7, etc.). Additionally, any circuitry coupled to the substrate 171 may include semiconductor chip substrate 172.

In one example, each of the substrate 171 and substrate 172 is a monolithic semiconductor substrate.

Further, as previously discussed, the second circuitry above the substrate 171 in the stack 198-1 may include switch circuitry 132 and corresponding driver circuitry 151. The driver circuitry 151 may be coupled to a surface of the first semiconductor chip substrate 171 over the inactive region 131-6. The second switch circuitry 132 may be coupled to the surface of the first semiconductor chip substrate 171 over the active region 131-7.

Yet further, as previously discussed, it is noted that the active regions 131-1, 131-2, 131-3, etc., may generate respective heat when such switch circuitry is activated. Conversely, the inactive regions of the of the first semiconductor chip substrate 171 do not generate heat because they do not support conveyance of corresponding current through the substrate 171.

Still further, it is noted again that the first switch circuitry 131 and corresponding substrate 171 may be affixed to the host substrate 141. As further shown, the substrate 171 may be disposed between the switch circuitry 132 and the host substrate 141.

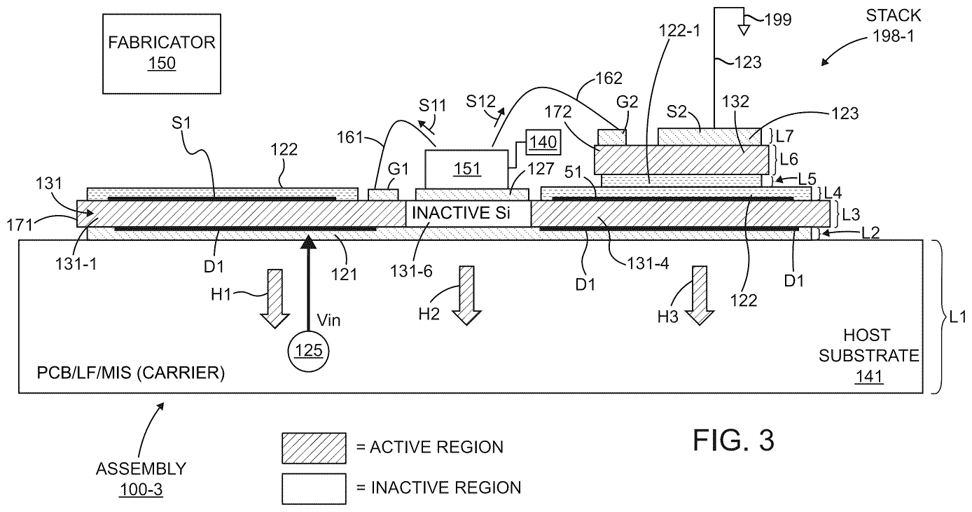

FIG. 3 is an example diagram illustrating a switch circuit assembly as discussed herein.

As shown in this example, the assembly 100-3 is generally identical to the assembly 100-1. However, in this example, the inactive region 131-7 is removed, resulting in only the inactive region 131-6 of the substrate 171 (and electrically conductive path or material layer 127, and a portion of the electrically conductive path 121) disposed between the driver circuitry 151 and the host substrate 144.

Accordingly, the substrate 171 in layer L3 advantageously includes inactive region such as inactive region 131-6 which is void of active circuitry and is a region that does not support flow of current from the drain node D1 to the source node S1 during activation of the respective switch circuitry 131 to an on state. This prevents generation of heat in the inactive region 131. Conversely, during activation of the respective switch circuitry 131 to an on state, the active regions 131-1, 131-4, etc., in the substrate 171 support flow of a respective current from the input voltage Vin and corresponding current received at the drain node D1 through the active regions (131-1, 131-4) to the corresponding source node S1.

As previously discussed, it is noted again that operation of the driver circuitry 151 results in generation of heat H2 that is conveyed through the inactive region 131-6 of the substrate 171. The void of activate circuitry in the inactive region 131-6 reduces the amount of heat that would otherwise need to be transferred to the host substrate 141 if the inactive region 131-6 was active circuitry providing a low impedance path. In other words, because the inactive region 131-6 does not include circuitry that generates heat, the inactive region 131-6 itself does not produce heat during activation of the switch circuit 131, enabling the inactive region 131-6 supporting easier conveyance of heat H2 generated by the driver circuitry 151 through the inactive region 131-6 to the host substrate 141.

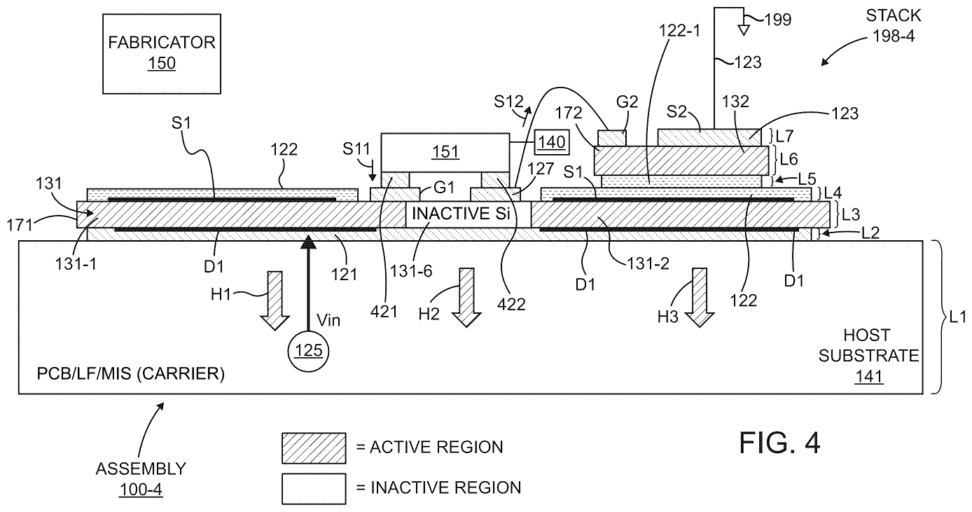

FIG. 4 is an example diagram illustrating a switch circuit assembly including a flipped driver circuit as discussed herein.

The assembly 100-4 and corresponding components operate in a similar manner as previously discussed. However, the assembly 100-4 as shown in FIG. 4 includes a minor modification associated with the driver circuitry 151 and corresponding connectivity to the switch circuitry.

More specifically, in this example, the assembly 100-4 includes the electrically conductive path 421 disposed in the layer L5 to convey the control signal S11 generated by the driver circuitry 151 to the gate node G1 of the switch 131 fabricated in the substrate 171. Additionally, the assembly 100-4 includes the corresponding electrically conductive path 422 to convey the respective control signal S12 generated by the driver circuitry 151 to the gate node G2 of the switch circuitry 132 fabricated in the substrate 172 of layer L6.

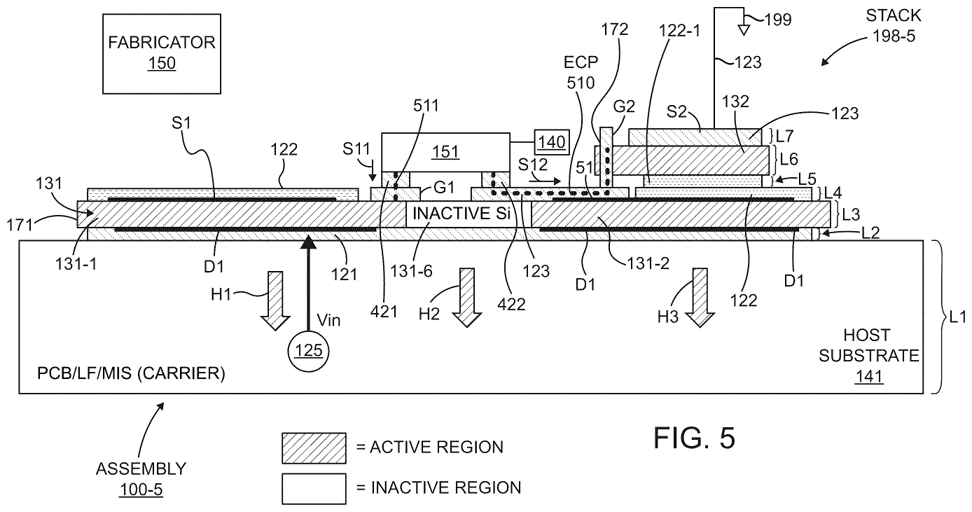

FIG. 5 is an example diagram illustrating a switch circuit assembly including a flipped driver circuit as discussed herein.

The assembly 100-5 and corresponding components operate in a similar manner as previously discussed. However, the assembly 100-5 and corresponding stack 198-5 includes a minor modification associated with the driver circuitry 151 and corresponding connectivity to the switch circuitry 132.

More specifically, in this example, the assembly 100-5 includes the electrically conductive path 511 disposed in one or more layers of the stack 198-5 to convey the control signal S11 generated by the driver circuitry 151 to the gate node G1 of the switch 131 fabricated in the substrate 171. Additionally, the assembly 100-5 includes the electrically conductive path 510 disposed in in one or more layers of the stack 198-5 to convey the control signal S12 generated by the driver circuitry 151 to the gate node G2 of the switch 132 fabricated in the substrate 172.

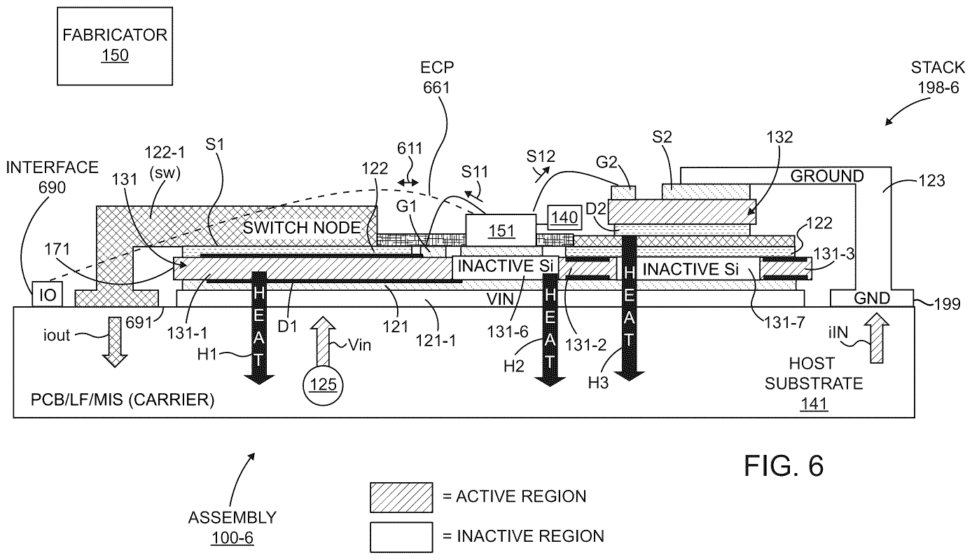

FIG. 6 is an example diagram illustrating implementation of one or more metal clips in a switch circuit assembly as discussed herein.

As previously discussed, the switch circuitry 132 may be a low side switch of a respective power converter. In this example, the stack 198-6 of circuit components may include: i) a first electrically conductive path 121-1 and electrically conductive path 121 (such as one or more layers of electrically conductive material such as metal) extending from a surface 691 of the host substrate 141 to a first node (such as drain node D1) of the switch 131 such as a high side switch, wherein the switch 131 is disposed between the source node S1 of the switch 131 and the surface 691 of the host substrate 141, and ii) a second electrically conductive path 123 extending from the surface 691 and reference voltage 199 of the host substrate 141 to a source node S2 of the switch 132, wherein a combination of the switch 132 and a portion of the first semiconductor chip substrate 171 are disposed between the source node S2 and the surface 691 of the host substrate 141.

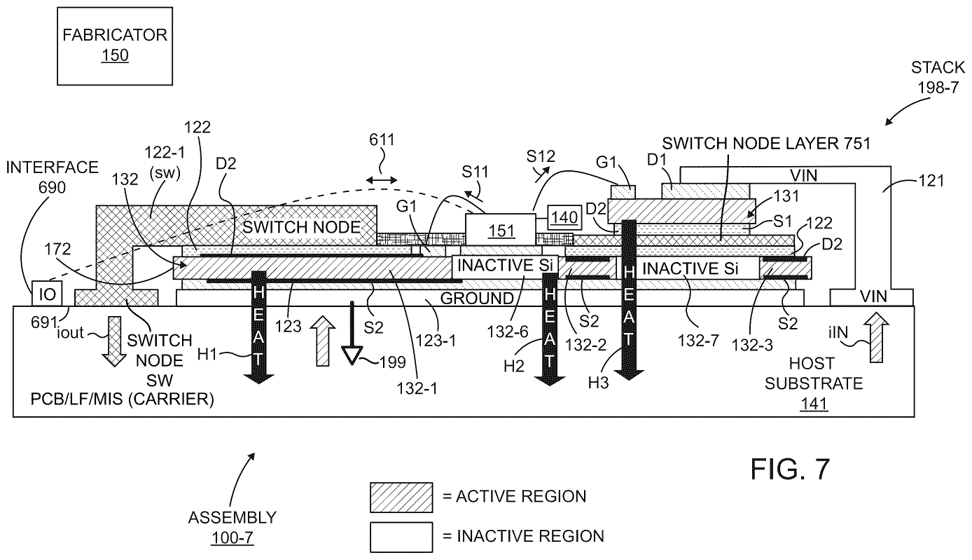

FIG. 7 is an example diagram illustrating implementation of one or more metal clips in the switch circuit assembly as discussed herein.

In this example, the assembly 100-7 implementing the switch circuit 101 includes stack 198-7 of circuit components (such as layers of metal, active circuitry, etc.). The stack 198-7 includes the second switch circuitry 132 such as fabricated in the substrate 172, which is coupled to the substrate 141 via the electrically conductive path 123-1 and electrically conductive path 123. The substrate 141 provides the ground reference voltage 199 to the source node S2 of the switch circuitry 132 through the electrically conductive path 123 and electrically conductive path 123-1. The electrically conductive path 122 and electrically conductive path 122-1 (such as switch node SW) extend from the drain node D2 of the switch circuitry 132 to the surface 691 of the host substrate 141 and the substrate 141 itself. The electrically conductive path 122-1 conveys the output current iout.

Accordingly, the assembly 100-7 and corresponding stack 198-7 can be configured to include: i) a first electrically conductive path (such as one or more of electrically conductive path 123, electrically conductive path 123-1) extending from the surface 691 of the host substrate 141 to a source node S2 of the switch circuitry 132, wherein the switch circuitry 132 is disposed between the drain node D2 of the switch circuitry 132 and the surface 691 of the host substrate 141, and ii) a second electrically conductive path 122 extending from the surface 691 of the host substrate 141 to a drain node D1 of the switch circuitry 131, wherein a combination of the switch circuitry 131 and a portion of the semiconductor chip substrate 172 are disposed between the drain node D1 of the switch circuitry 131 and the surface 691 of the host substrate 141. In this example, the active regions 132-1, 132-2, 132-3, etc., in the substrate 172 represent the switch circuitry 132 and provide control of perspective current through same. The substrate 172 includes inactive region 132-6 and inactive region 132-7.

In a similar manner as previously discussed, the inactive regions 132-6 and 132-7 do not include active circuitry or support current flow and therefore do not generate heat. However, the inactive region 132-6 in the substrate 172 is configured to provide a good thermally conductive path to convey heat H2 from the driver circuitry 151 through the inactive region 132-6 to the host substrate 141. The inactive region 132-7 in the substrate 172 is configured to provide a good thermally conductive path to convey heat H3 from the switch circuitry 131 through the inactive region 132-7 to the host substrate 141.

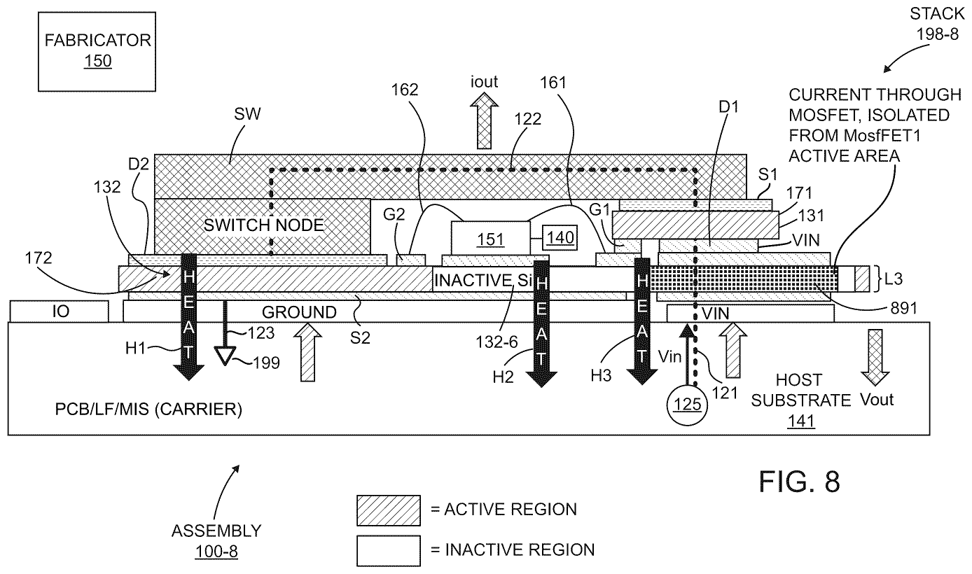

FIG. 8 is an example diagram illustrating implementation of electrically conductive path connect multiple switches in a switch circuit assembly as discussed herein.

In this example, the switch circuitry 132 is disposed in the substrate 172 coupled to the host substrate 141 via the electrically conductive path 123. The electrically conductive path 123 provides the ground reference voltage 199 to the source node S2 of the switch circuitry 132. A top side of the switch circuitry 132 and the substrate 172 includes the drain node D2. Via the electrically conductive path 122, the drain node D2 is connected to the source node S1 of the switch circuitry 131 disposed in the substrate 171.

In a similar manner as prissy discussed, the substrate 172 can be configured to include inactive region 132-6 supporting thermal flow of heat from the driver circuitry 151 to the host substrate 141.

As further shown, the stack 198-8 can be configured to include connectivity of the source node S1 associated with the switch circuitry 131 fabricated in the substrate 171 via the electrically conductive paths 891 (such as vias, silicon vias, etc.) fabricated in the substrate 172. As shown, the electrically conductive path 121 from the input voltage source 125 through the electrically conductive paths in 891 conveys the input voltage Vin to the source node S1 of the switch circuitry 131.

Thus, the implementation of the stack 198-8 assembly 100-8 can be configured to include: an electrically conductive path 122 extending between a first node such as the source node S1 of the first switch circuitry 131 and a first node such as the drain node D2 of the second switch circuitry 132.

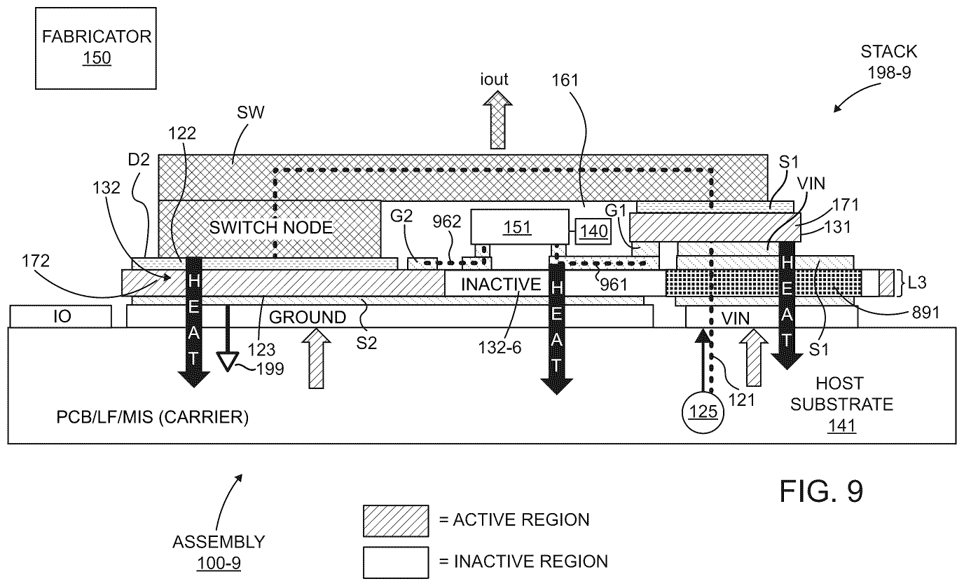

FIG. 9 is an example diagram illustrating implementation of electrically conductive path connecting multiple switches and the switch circuit assembly as discussed herein.

The configuration of the assembly 100-9 is similar or the same as the assembly 100-8 except that the stack 198-9 includes the electrically conductive path 961 and the electrically conductive path 962.

For example, the stack 198-9 of the assembly 100-9 includes the electrically conductive path 961 to convey the signal S11 generated by the driver circuitry 151 to the gate node G1 of the switch circuitry 131. The stack 198-9 of the assembly 100-9 further includes the electrically conductive path 962 to convey the signal S12 generated by the driver circuitry 151 to the gate node G2 of the switch circuitry 132.

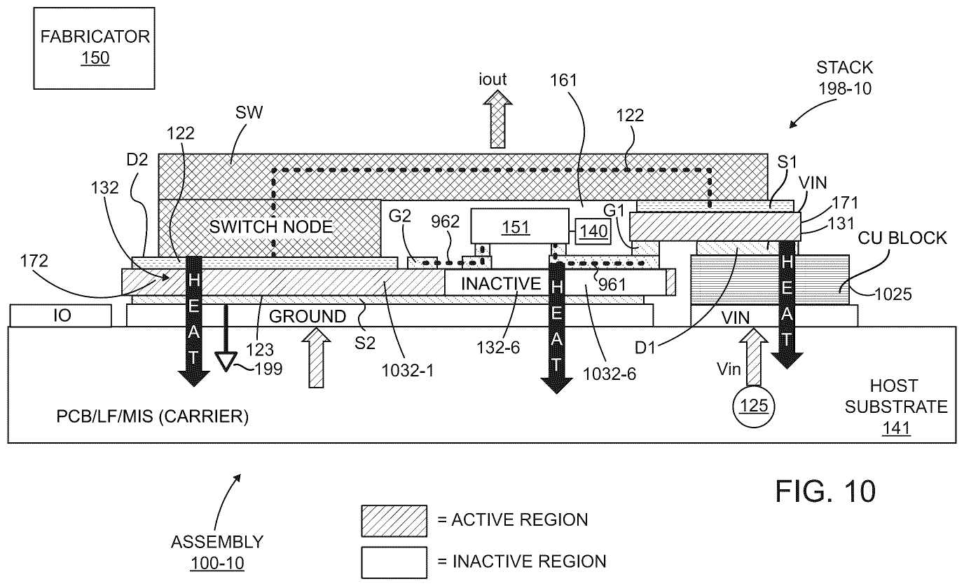

FIG. 10 is an example diagram illustrating implementation of a metal layer providing electrical connectivity of a switch in a switch circuit assembly to a host substrate as discussed herein.

The configuration of the assembly 100-10 is similar or the same as the assembly 100-9 except that the stack 198-10 includes the electrically conductive path 1025 such as fabricated from metal or other suitable electrically conductive material.

For example, the stack 198-10 of the assembly 100-10 includes the electrically conductive path 961 to convey the signal S11 generated by the driver circuitry 151 to the gate node G1 of the switch circuitry 131. The stack 198-9 of the assembly 100-9 further includes the electrically conductive path 962 to convey the signal S12 generated by the driver circuitry 151 to the gate node G2 of the switch circuitry 132.

The source node S2 of the switch circuitry 132 fabricated in substrate 172 receives the ground reference voltage 199 from the substrate 141 via the electrically conductive path 123. The drain node D2 of the switch circuitry 132 is electrically connected to the source node S1 of switch circuitry 131 via the electrically conductive path 122 such as the switch node SW. The active region 1032-1 of the substrate 172 represents the switch circuitry 132 and provides high impedance or low impedance connectivity between the drain node D2 and the source node S2 based upon the control signal 962 supplied to the gate node G2.

The active region of the switch circuitry 131 and corresponding substrate 171 partially overlap the inactive region 1032-6 of substrate 172. The inactive region 1032-6 supports conveyance of respective heat from the driver circuitry 151 to the substrate 141 as well as heat from the switch circuitry 131 to the substrate 141. Additionally, the heat generated by the switch circuitry 131 in substrate 171 is able to flow through the electrically conductive path 1025 to the substrate 141. In a reverse direction, the power source 125 associated with the substrate 141 supplies the input voltage Vin to the electrically conductive path 1025. The electrically conductive path 1025 conveys the input voltage Vin and corresponding current to the drain node D1 of the switch circuitry 131. Activation of the switch circuitry 131 via the control signal S 11 conveyed over the electrically conductive path 961 produces a low impedance path from the drain node D1 to the source node S1, resulting in conveyance of the input voltage Vin and corresponding current to the electrically conductive path 122.

Thus, the assembly as discussed herein can be can to include the semiconductor chip substrate 172 disposed in a first material layer of a component stack. The stack 198-10 can be configured to include the electrically conductive path 1025 adjacent to the substrate 172 and corresponding layer. The electrically conductive path 1025 directly couples the drain node D1 of the switch circuitry 131 to the power source 125. As further shown, the electrically conductive path 122 directly connects the switch circuitry 131 and switch circuitry 132 in series.

The driver circuitry 151 may be disposed adjacent to switch circuitry 131 and above the inactive region 1032-6 of the substrate 172.

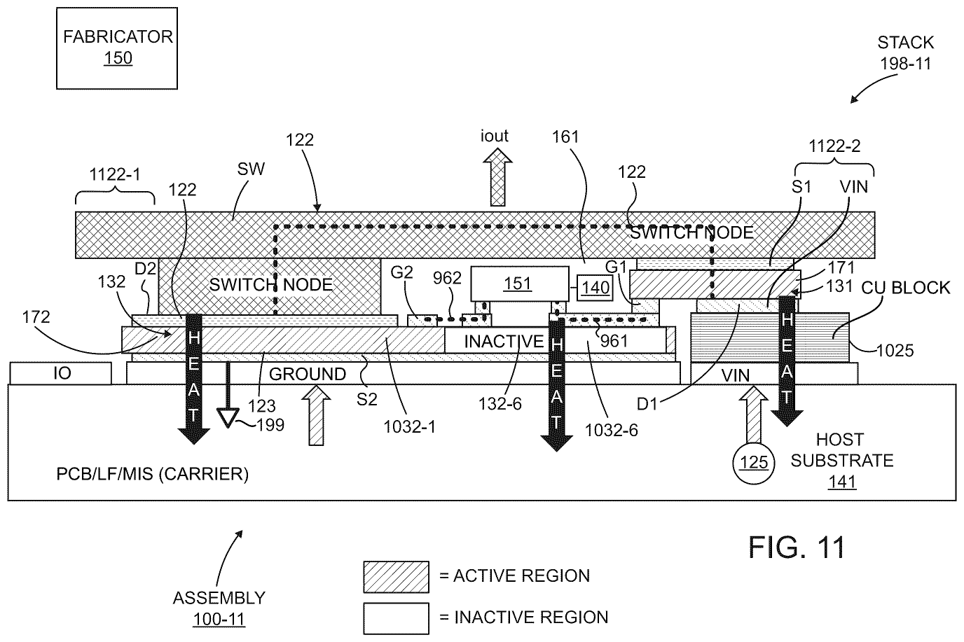

FIG. 11 is an example diagram illustrating implementation of a metal layer providing electrical connectivity of a switch in a switch circuit assembly to a host substrate as discussed herein.

In this example, the electrically conductive path 122 is configured to include extra material 1122-1 to fabricate the electrically conductive path 122, where the material 1122-1 overhangs the left edge of the substrate 172 to provide better heatsink capability. Additionally, note that the electrically conductive path 122 is further configured to include extra material 1122-2 that overhangs the right edge of the switch circuitry 131 and the electrically conductive path 1025.

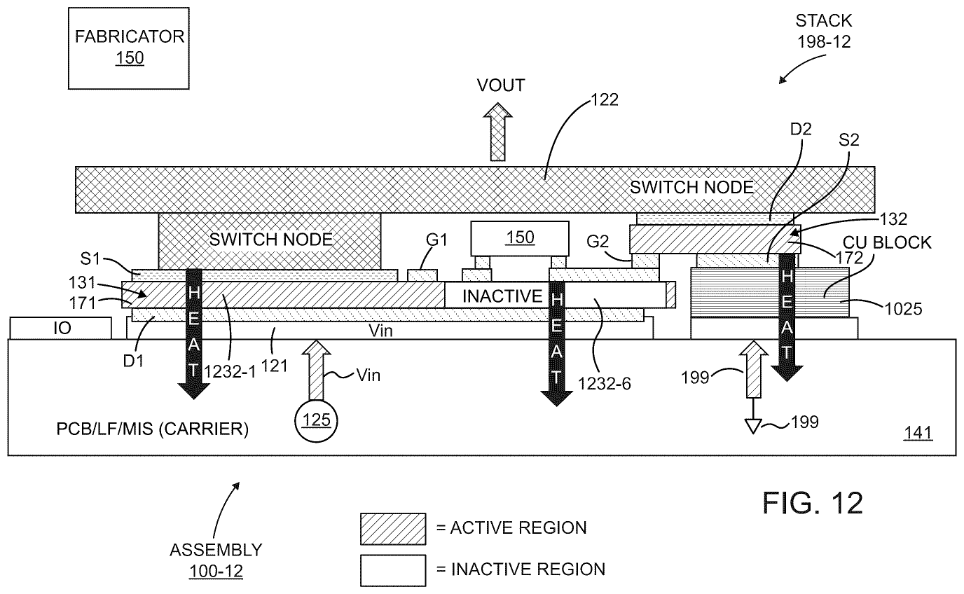

FIG. 12 is an example diagram illustrating implementation of a metal layer providing electrical connectivity of a switch in a switch circuit assembly to a host substrate as discussed herein.

In this example, the switch circuitry 131 is disposed in the substrate 171 and is coupled directly to the host substrate 141 via the electrically conductive path 121. The electrically conductive path 121 provides the input voltage Vin received from the input voltage power source 125 to the drain node D1 of the switch circuitry 131 disposed in the substrate 171. The active region 1232-1 of the substrate 131 represents the switch circuitry 131. A top side of the switch circuitry 131 and the corresponding substrate 171 includes the source node S1 directly coupled to the electrically conductive path 122. Thus, via the electrically conductive path 122, the source node S1 is connected to the drain node D2 as shown.

In a similar manner as previously discussed, the substrate 171 can be configured to include inactive region 1232-6 supporting thermal flow of heat from the driver circuitry 151 and/or the switch circuitry 132 to the host substrate 141.

As further shown, the stack 198-12 of the assembly 100-12 can be configured to include the electrically conductive path 1025 to connect the source node S2 associated with the switch circuitry 132 (which is fabricated in the substrate 172) to the ground reference voltage 199 associated with the substrate 141. In other words, the combination of the electrically conductive path 1025 (such as metal or other suitable material) and activation of the switch circuitry 132 electrically connects the electrically conductive path 122 (switch node SW) to the ground reference voltage 199.

Thus, activation of the switch circuitry 131 conveys the input voltage Vin to the electrically conductive path 122. Activation of the switch circuitry 132 electrically connects the electrically conductive path 122 to the ground reference voltage 199.

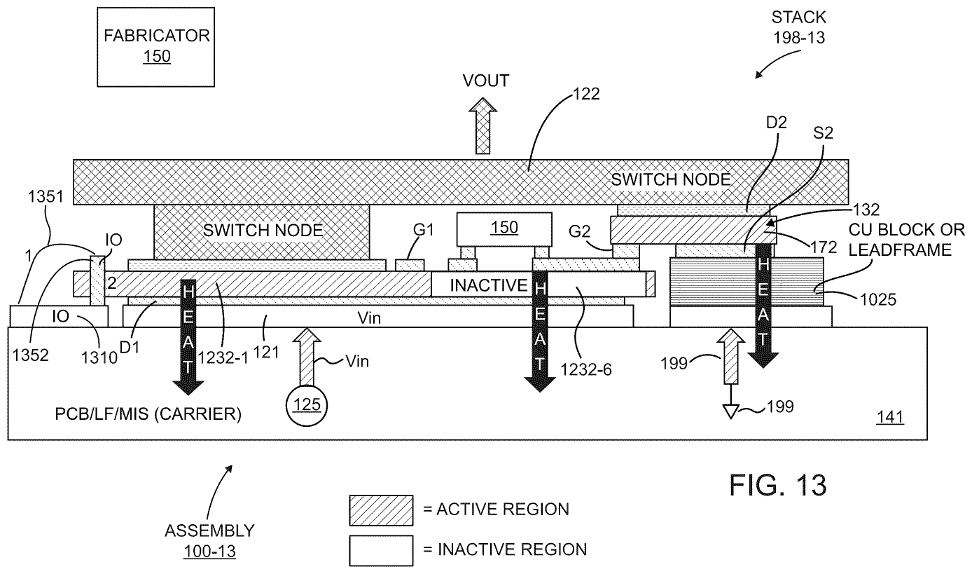

FIG. 13 is an example diagram illustrating implementation of a metal layer providing electrical connectivity of a switch in a switch circuit assembly to a host substrate as discussed herein.

In this example, the assembly 100-13 includes the stack 198-13 of components as previously discussed as well as the circuitry 1310 (such as receiving and transmitting signals) over the electrically conductive path 1351 (such as one or more wire bonds) and/or the electrically conductive path 1352 (such as through silicon vias) to the circuitry in the stack 198-13.

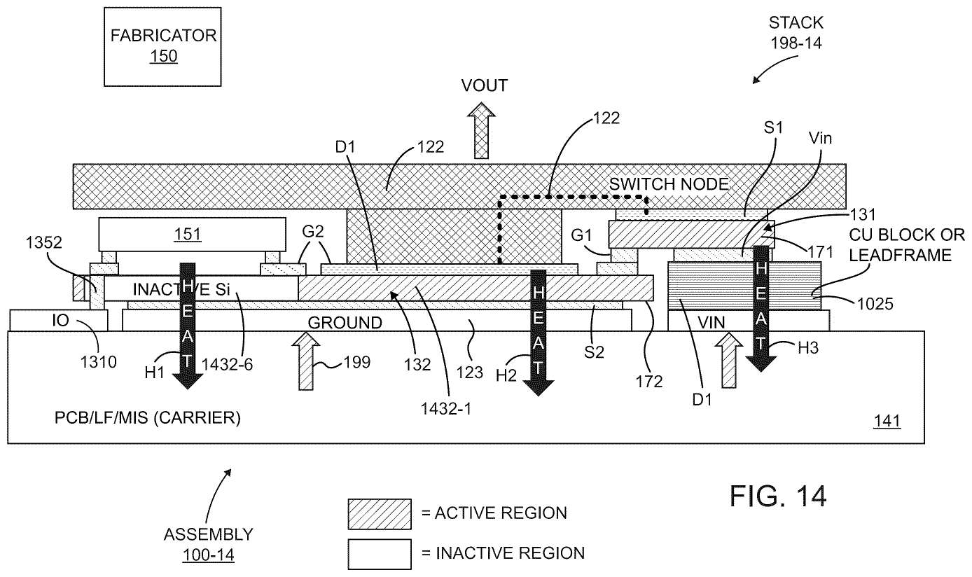

FIG. 14 is an example diagram illustrating implementation of a metal layer providing electrical connectivity of a switch in a switch circuit assembly to a host substrate as discussed herein.

In this example, the driver circuitry 151 is disposed over the inactive region 1432-6 of the substrate 172. The active region 1432-1 of the substrate 172 represents the switch circuitry 132 including the source node S2 directly coupled to the ground reference voltage 199 and the drain node D1 directly connected to the electrically conductive path 122. As previously discussed, the driver circuitry 151 produces control signal S12 applied to the gate node G2 of the switch circuitry 132. Additionally, the driver circuitry 151 produces the control signal S11 applied to the gate node G1 of the switch circuitry 131 disposed in the substrate 171.

Further, in a similar manner as previously discussed, the heat H1 produced by the driver circuitry 151 is conveyed through the inactive region 1432-6 of the substrate 172 to the host substrate 141. The heat H2 produced by the switch circuitry 132 is conveyed through the electrically conductive path 123 to the substrate 141. The heat H3 produced by the switch circuitry 131 is conveyed through the electrically conductive path 1025 to the host substrate 141.

Accordingly, the switch circuitry 132 in the active region 1432-1 of the semiconductor chip substrate 172 is disposed in a first layer of the stack 198-14, where the first layer is disposed between the inactive region 1432-6 in the electrically conductive path 1025. The switch circuitry 131 and corresponding semiconductor chip substrate 171 is disposed in a layer of the stack 198-14 above the layer including the switch circuitry 132.

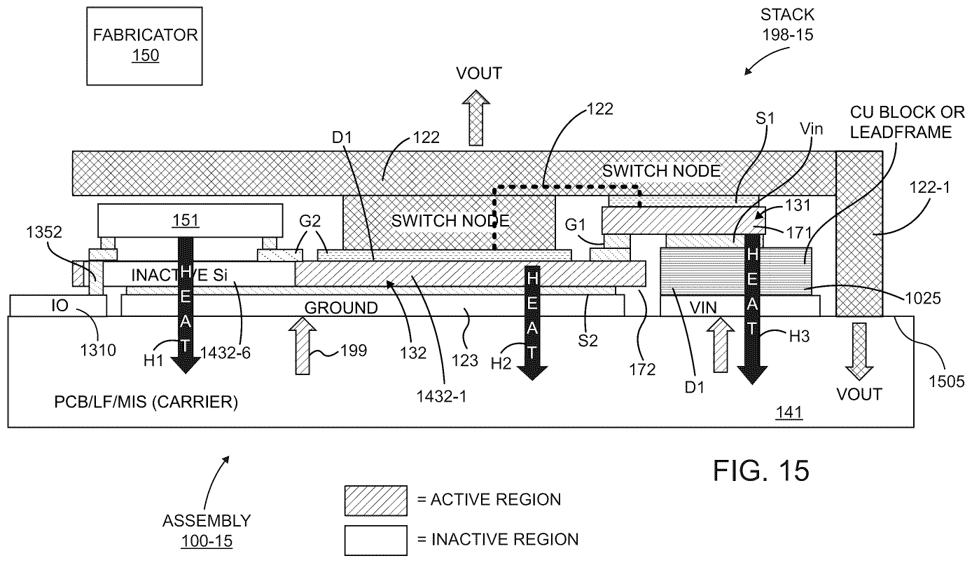

FIG. 15 is an example diagram illustrating implementation of a metal layer providing electrical connectivity of a switch in a switch circuit assembly to a host substrate as discussed herein.

As shown in FIG. 15, the assembly 100-14 and corresponding stack 198-14 in FIG. 14 can be modified to produce the assembly 100-15 and corresponding stack 198-15. For example, the stack 198-15 and thus assembly 100-15 can be configured to additionally include electrically conductive path 122-1 coupled to the electrically conductive path 122 to convey the voltage (such as Vout) and corresponding output current iout from the switch node SW to the substrate 141.

Thus, the stack 198-15 can be configured to include the electrically conductive path 122 and electrically conductive path 122-1. The electrically conductive path 122 connects the switch circuitry 131 and switch circuitry 132 in series. The electrically conductive path 122-1 extends between the electrically conductive path 122 and corresponding switch node SW to the surface 1505 of the host substrate 141.

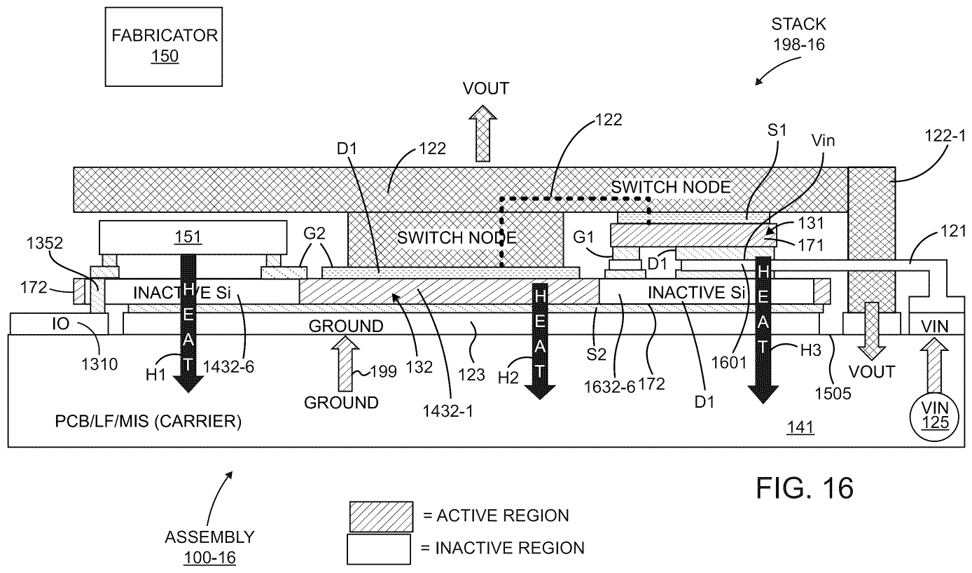

FIG. 16 is an example diagram illustrating implementation of a metal layer providing electrical connectivity of a switch in a switch circuit assembly to a host substrate as discussed herein.

As shown in FIG. 16, the assembly 100-15 and corresponding stack 198-15 in FIG. 15 can be modified to produce the assembly 100-16 and corresponding stack 198-16. For example, the stack 198-16 and thus assembly 100-16 can be configured to include electrically conductive path 121 to convey the input voltage Vin from the input voltage source 125 to the drain node D1 of the switch circuitry 131 disposed in the substrate 171.

Thus, the stack 198-16 can be configured to include the electrically conductive path 122, electrically conductive path 122-1, and electrically conductive path 121. The electrically conductive path 122 connects the switch circuitry 131 and switch circuitry 132 in series. The electrically conductive path 122-1 extends between the electrically conductive path 122 and corresponding switch node SW to the surface 1505 of the host substrate 141. The electrically conductive path 121 extends between the drain node D1 of the switch circuitry 131 and the host substrate 141 to convey the input voltage from the source 125.

As further shown, a first portion of the electrically conductive path 121 such as a circuit node 1601 is sandwiched between the substrate 171 and the inactive region 1632-6 of the substrate 172 providing connectivity between the switch circuitry 131 (active region of the substrate 171) and the inactive region 1632-6 of the substrate 172. A second portion of the electrically conductive path 121 extends between the circuit node 1601 and a surface 1505 of the host substrate 141.

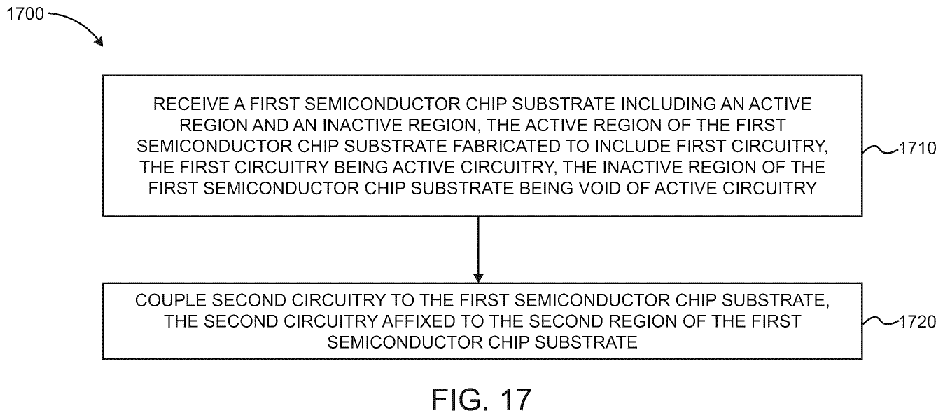

FIG. 17 is an example method associated with operation of switch driver circuitry as discussed herein.

In processing operation 1710 of flowchart 1700, the fabricator 150 receives a first semiconductor chip substrate (such as substrate 131 or layer L3) including: i) one or more active region such as regions 131-1, 131-2, 131-3, etc., including so-called active circuitry such as representing a first switch 131, and ii) one or more inactive regions such as one or more regions 131-6, 131-7, etc., including so-called inactive circuitry such as regions void of active circuitry (such as no circuitry at all or non-functioning circuitry). In one example, the combination of active regions such as active regions 131-1, 131-2, 131-3, etc., represent first circuitry (or so-called active circuitry) such as a first switch 131. As previously discussed, the benefit of including regions in the substrate 131 such as inactive silicon (such as one or more regions 131-6, 131-7, etc.) is that such regions support conveyance of heat to a respective host substrate 141 without themselves generating heat because there is no active circuitry.

In processing operation 1720, the fabricator 150 provides coupling of second circuitry (such as including the switch 132) to the first semiconductor chip substrate 131 (layer L3), where the second circuitry (such as including the switch 132) are affixed to the second region (such as one or more of regions 131-6, 131-7, etc.) of the first semiconductor chip substrate (layer L3).

Note again that techniques herein are well suited for use in switch circuit assemblies. However, it should be noted that examples herein are not limited to use in such applications and that the techniques discussed herein are well suited for other applications as well.

Based on the description set forth herein, numerous specific details have been set forth to provide a thorough understanding of claimed subject matter. However, it will be understood by those skilled in the art that claimed subject matter may be practiced without these specific details. In other instances, methods, apparatuses, systems, etc., that would be known by one of ordinary skill have not been described in detail so as not to obscure claimed subject matter. Some regions of the detailed description have been presented in terms of algorithms or symbolic representations of operations on data bits or binary digital signals stored within a computing system memory, such as a computer memory. These algorithmic descriptions or representations are examples of techniques used by those of ordinary skill in the data processing arts to convey the substance of their work to others skilled in the art. An algorithm as described herein, and generally, is considered to be a self-consistent sequence of operations or similar processing leading to a desired result. In this context, operations or processing involve physical manipulation of physical quantities. Typically, although not necessarily, such quantities may take the form of electrical or magnetic signals capable of being stored, transferred, combined, compared or otherwise manipulated. It has been convenient at times, principally for reasons of common usage, to refer to such signals as bits, data, values, elements, symbols, characters, terms, numbers, numerals or the like. It should be understood, however, that all of these and similar terms are to be associated with appropriate physical quantities and are merely convenient labels. Unless specifically stated otherwise, as apparent from the following discussion, it is appreciated that throughout this specification discussions utilizing terms such as “processing,” “computing,” “calculating,” “determining” or the like refer to actions or processes of a computing platform, such as a computer or a similar electronic computing device, that manipulates or transforms data represented as physical electronic or magnetic quantities within memories, registers, or other information storage devices, transmission devices, or display devices of the computing platform.

While this invention has been particularly shown and described with references to preferred examples thereof, it will be understood by those skilled in the art that various changes in form and details may be made therein without departing from the spirit and scope of the present application as defined by the appended claims. Such variations are intended to be covered by the scope of this present application. As such, the foregoing description of examples of the present application is not intended to be limiting. Rather, any limitations to the invention are presented in the following claims.

1. An assembly comprising:
a first semiconductor chip substrate including an active region and an inactive region, the active region of the first semiconductor chip substrate fabricated to include first circuitry, the first circuitry being active circuitry, the inactive region of the first semiconductor chip substrate being void of active circuitry; and
second circuitry coupled to the first semiconductor chip substrate, the second circuitry affixed to the inactive region of the first semiconductor chip substrate, the inactive region operative to receive and convey heat generated by the second circuitry.

2. The assembly as in claim 1, wherein the second circuitry includes driver circuitry coupled to the first semiconductor chip substrate, the driver circuitry operative to control operation of the first circuitry.

3. The assembly as in claim 2, wherein the first circuitry includes a first switch controlled by the driver circuitry; and
wherein the second circuitry includes a second switch controlled by the driver circuitry.

4. The assembly as in claim 1, wherein the first circuitry is a first vertical field effect transistor.

5. The assembly as in claim 4, wherein the second circuitry is a second vertical field effect transistor.

6. The assembly as in claim 5 further comprising:
a first layer of metal disposed on a first surface of the first semiconductor chip substrate; and
a second layer of metal disposed on a second surface of the first semiconductor chip substrate, the second surface disposed opposite the first surface.

6. The assembly as in claim 5, wherein the first circuitry is a first switch;
wherein a source node of the first switch is directly coupled to the first layer of metal; and
wherein a drain node of the second switch circuitry is directly coupled to the first layer of metal.

7. The assembly as in claim 1, wherein the inactive region of the first semiconductor chip substrate provides a thermally conductive path between a first surface of the first semiconductor chip substrate through the inactive region to a second surface of the first semiconductor chip substrate.

8. The assembly as in claim 1, wherein the first semiconductor chip substrate is a first monolithic semiconductor substrate including the active region and the inactive region; and
wherein the second circuitry includes a second semiconductor chip substrate, the second semiconductor chip substrate being a second monolithic semiconductor substrate.

9. The assembly as in claim 1, wherein the first circuitry is a first switch;
wherein the second circuitry is a second switch, the assembly further comprising:
an electrically conductive path coupling the first switch and the second switch, the electrically conductive path operative to directly coupled a source node of the first switch to a drain node of the second switch.

10. The assembly as in claim 1, wherein the inactive region includes a first portion and a second portion separated by a portion of the active region.

11. The assembly as in claim 1 further comprising:
an electrically conductive path extending between a first node of the first switch and a first node of the second switch; and
wherein the first node of the first switch is disposed between the first semiconductor chip substrate and the electrically conductive path; and
wherein the second circuitry is disposed between the electrically conductive path and the first semiconductor chip substrate.

12. The assembly as in claim 11, wherein the first circuitry is a first switch;
wherein the second circuitry includes a second switch and driver circuitry, the driver circuitry operative to control operation of the first switch and the second switch, the driver circuitry coupled to a surface of the first semiconductor chip substrate over the first portion of the inactive region, the second switch coupled to the surface of the first semiconductor chip substrate over the second portion of the inactive region.

13. The assembly as in claim 1, wherein the active region of the first semiconductor chip substrate is operative to generate heat; and
wherein the inactive region of the first semiconductor chip substrate is not operative to generate heat.

14. An apparatus comprising:
a host substrate; and
the assembly of claim 1 coupled to the host substrate, wherein the first circuitry is affixed to a surface of the host substrate, the first semiconductor chip substrate disposed between the second circuitry and the host substrate.

15. The apparatus as in claim 14, wherein the first circuitry is a high side switch of a power converter;
wherein the second circuitry is a low side switch of the power converter; and
the apparatus further comprising: i) a first electrically conductive path extending from the surface of the host substrate to a first node of the high side switch, wherein the high side switch is disposed between the first node of the high side switch and the surface of the host substrate, and ii) a second electrically conductive path extending from the surface of the host substrate to a first node of the low side switch, wherein a combination of the low side switch and the first semiconductor chip substrate are disposed between the first node of the low side switch and the surface of the host substrate.

16. The apparatus as in claim 14, wherein the first circuitry is a low side switch of a power converter;
wherein the second circuitry is a high side switch of the power converter; and
the apparatus further comprising: i) a first electrically conductive path extending from the surface of the host substrate to a first node of the low side switch, wherein the low side switch is disposed between the first node of the low side switch and the surface of the host substrate, and ii) a second electrically conductive path extending from the surface of the host substrate to a first node of the high side switch, wherein a combination of the high side switch and the first semiconductor chip substrate are disposed between the first node of the high side switch and the surface of the host substrate.

17. The assembly as in claim 1, wherein the first semiconductor chip substrate is disposed in a first material layer of a component stack, the assembly further comprising:
a first electrically conductive path disposed in the first material layer adjacent to the first semiconductor chip substrate, the electrically conductive path coupled to a first node of the second circuitry; and
a second electrically conductive path directly connecting the first circuitry and the second circuitry in series.

18. The assembly as in claim 17, wherein the first circuitry includes a first switch;
wherein the second circuitry includes a second switch;
wherein the inactive region of the first semiconductor chip substrate is disposed in the first material layer between the first switch and the first electrically conductive path; and
wherein the second circuitry includes driver circuitry disposed adjacent to the second switch and above the inactive region of the first semiconductor chip substrate.

19. A method comprising:
receiving a first semiconductor chip substrate including an active region and an inactive region, the active region of the first semiconductor chip substrate fabricated to include first circuitry, the first circuitry being active circuitry, the inactive region of the first semiconductor chip substrate being void of active circuitry; and
coupling second circuitry to the first semiconductor chip substrate, the second circuitry affixed to the inactive region of the first semiconductor chip substrate.
